(19) United States
(12) Patent Application Publication
(10) Pub. No.: US 2007/0147001 A1
(43) Pub. Date: Jun. 28, 2007

(54) Heat dissipating device

(75) Inventors: Mao-Ching Lin, Taipei (TW); Win-Haw Chen, Taipei (TW)

Correspondence Address: EDWARDS ANGELL PALMER & DODGE LLP, P.O. BOX 55874, BOSTON, MA, 02205, US

(73) Assignee: Inventec Corporation, Taipei (TW)

(21) Appl. No.: 11/395,934

(22) Filed: Mar. 30, 2006

(30) Foreign Application Priority Data
Dec. 22, 2005 (TW) 94222407

(51) Int. Cl. H05K 7/20

(52) U.S. Cl. 361/704

(57) ABSTRACT

A heat dissipating device for a heat generating component mounted on a frame-shaped carrier, includes a heat sink block, and a base having a top surface and a bottom surface. The heat sink block is mounted on the top surface of the base. A coupling board is formed on each of two opposite sides of the base at a position close to the bottom surface and lower in height than the top surface of the base. The coupling board is formed with an installing portion for being coupled to a coupling portion of the frame-shaped carrier, so as to fix the base to the frame-shaped carrier via the coupling board and allow the bottom surface of the base to cover the heat generating component on the frame-shaped carrier, to thereby make the heat sink block have a maximum heat dissipating area to dissipate heat generated by the heat generating component.

### FIELD OF THE INVENTION

The present invention relates to heat dissipating devices, and more particularly, to a heat dissipating device for dissipating heat generated a heat generating electronic component.

### BACKGROUND OF THE INVENTION

Central Processing Unit (CPU) is a main component of a computer, for providing processing and central control functions for the computer, which is undoubtedly important. However, the CPU generates a large amount of heat during high-frequency operation, and a high temperature due to the heat may become a potential factor causing breakdown of the computer. Therefore, a heat dissipating device is developed to solve this problem.

Referring to FIG. 1, a conventional heat dissipating device 1 for dissipating the heat from the CPU comprises a heat sink block 11 and a frame 12 where the heat sink block 11 is mounted. The heat sink block 11 comprises a plurality of heat sink fins 11 for heat dissipation, and openings 110 formed on two sides of the heat sink block 11, for allowing screws 13 to pass through springs 14 and the openings 110 to be screwed to the frame 12, such that the heat sink block 11 can be fixed on the frame 12. A heat generating component such as the CPU (not shown) is provided under the frame 12, and heat generated by the heat generating component can be transmitted to the heat dissipating device 1 and dissipated.

However, the prior art using screwing elements causes a drawback that heads of the screws would impede flow of heat during dissipation, thereby degrading the heat dissipating efficiency.

Therefore, the problem to be solved here is to provide a heat dissipating device to overcome the above drawback in the prior art.

### SUMMARY OF THE INVENTION

In light of the above drawback in the prior art, an objective of the present invention is to provide a heat dissipating device having a maximum heat dissipating area.

Another objective of the present invention is to provide a heat dissipating device to absorb evenly heat generated by a heat generating component.

In accordance with the above and other objectives, the present invention proposes a heat dissipating device for a heat generating component mounted on a frame-shaped carrier. The heat dissipating device comprises: a heat sink block; and a base having a top surface and a bottom surface, wherein the heat sink block is mounted on the top surface of the base, and a coupling board is formed on each of two opposite sides of the base at a position close to the bottom surface and lower in height than the top surface of the base. The coupling board is formed with an installing portion for being coupled to a coupling portion of the frame-shaped carrier, so as to fix the base to the frame-shaped carrier via the coupling board and allow the bottom surface of the base to cover the heat generating component on the frame-shaped carrier. The heat generating component is preferably located in a central area of the frame-shaped carrier. By using the coupling board, which is located lower in height than the top surface of the base, to fix the base to the frame-shaped carrier, the heat sink block can have a maximum heat dissipating area to dissipate heat generated by the heat generating component rapidly, and the drawback in the prior art that screwing elements impede flow of heat during dissipating can be avoided.

The heat generating component can be a CPU, or a semiconductor package that generates heat during operation thereof, etc.

The heat sink block comprises a plurality of heat sink fins arranged at intervals to increase the heat dissipating area. The coupling board can be integrally protruded from the base and extended horizontally in relation to the base. The installing portion of the coupling board can be an opening, and the coupling portion of the frame-shaped carrier can be a screw hole, such that the installing portion can be coupled to the coupling portion by a coupling member such as a bolt to connect the coupling board and the frame-shaped carrier together.

Compared with the conventional heat dissipating device having the screwing elements thereof that impede flow of heat during dissipation, the heat dissipating device of the present invention has the heat sink block mounted on the top surface of the base, and uses the coupling member provided to the coupling board to fix the base to the frame-shaped carrier where the heat generating component is mounted, wherein the coupling board is located lower in height than the top surface of the base, such that the heat sink block can have a maximum heat dissipating area, and flow of the heat from the heat generating component during dissipation would not be affected by the coupling board with the coupling member.

Furthermore, as the base is located between the heat sink block and the heat generating component, and the heat sink block is mounted on the top surface of the base, the heat from the heat generating component can be spread to the heat sink block evenly via the base, so as to avoid the heat being perpetually absorbed by a particular area of the heat sink block, such that the heat dissipating efficiency is not affected or degraded.

Therefore, the heat dissipating device of the present invention overcomes the drawback in the prior art and improves the heat dissipating efficiency as compared with the prior art.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a schematic diagram of a conventional heat dissipating device;

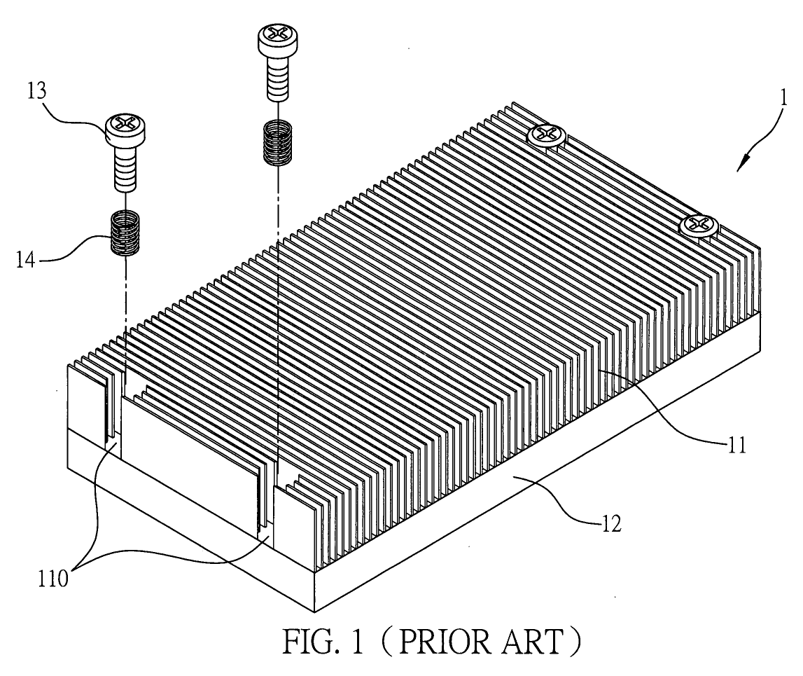

FIG. 2 is a schematic diagram of a heat dissipating device according to a preferred embodiment of the present invention;

FIG. 3 is a partially exploded schematic diagram of the heat dissipating device according to the present invention and a frame-shaped carrier where the heat dissipating device is to be mounted; and

FIG. 4 is an exploded schematic diagram of the heat dissipating device according to the present invention.

### DETAILED DESCRIPTION OF THE PREFERRED EMBODIMENTS

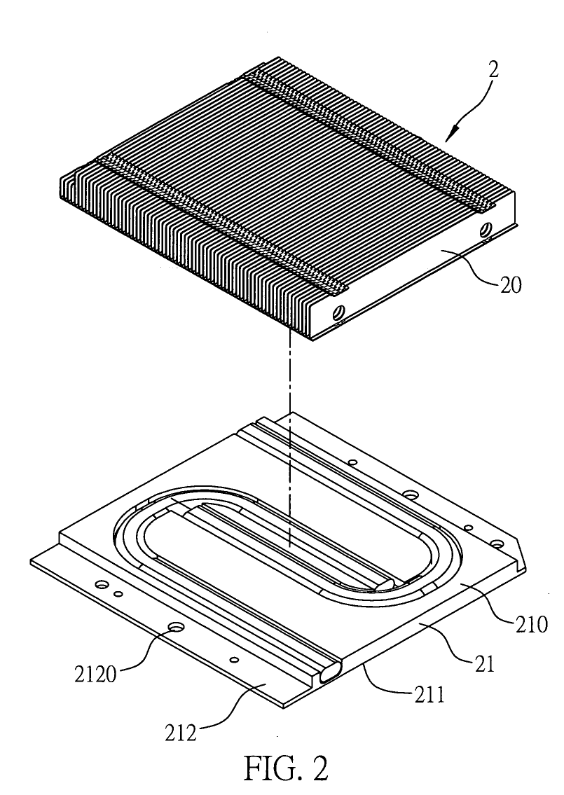

Preferred embodiments of a heat dissipating device proposed in the present invention are described as follows with reference to FIGS. 2 to 4. It is to be noted that the drawings are simplified schematic diagrams and only show components relating to the present invention. In practice, the layout of components could be more complicated. It should be understood that the following embodiments are not construed to limit the scope of the present invention.

As shown in FIG. 2, a heat dissipating device 2 of the present invention comprises a heat sink block 20 and a base 21. The base 21 has a top surface 210 and a bottom surface 211. The heat sink block 20 is mounted on the top surface 210 of the base 21. A coupling board 212 is formed on each of two opposite sides of the base 21 at a position close to the bottom surface 211 and lower in height than the top surface 210 of the base 21, wherein the coupling board 212 is formed with an installing portion 2120.

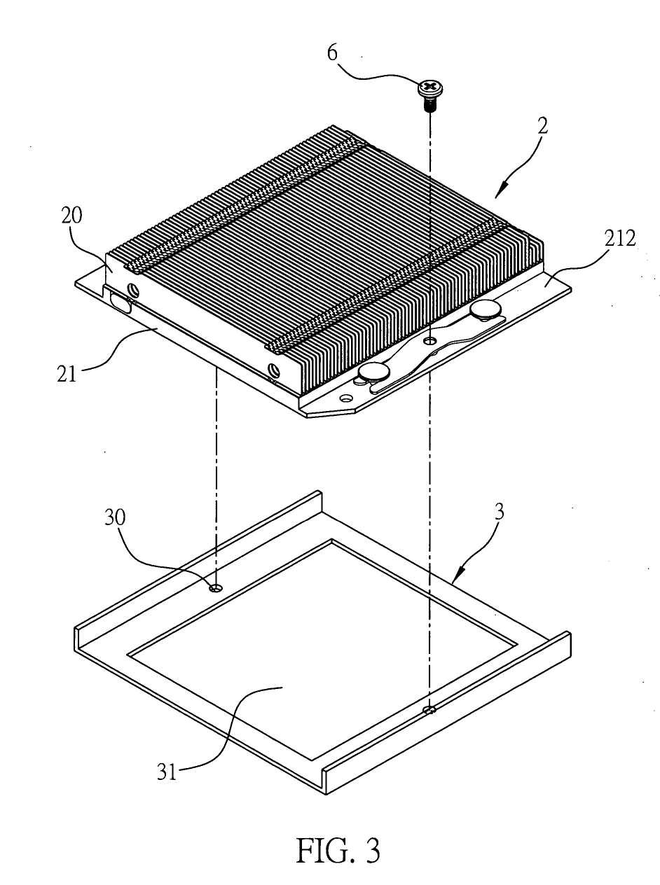

As shown in FIG. 3, the heat dissipating device 2 can be mounted on a frame-shaped carrier 3 with a heat generating component (not shown) being disposed in a central area 31 thereof. The frame-shaped carrier 3 is formed with a coupling portion 30 corresponding to the installing portion 2120 of the coupling board 212 on each of the two opposite sides of the base 21, wherein the installing portion 2120 can be coupled to the coupling portion 30. The heat dissipating device 2 further comprises a coupling member 6 for coupling the installing portion 2120 to the coupling portion 30 to fix the coupling board 212 to the frame-shaped carrier 3, such that the bottom surface 211 of the base 21 covers the heat generating component on the frame-shaped carrier 3. As the coupling board 212 for fixing the base 21 to the frame-shaped carrier 3 is located lower in height than the top surface 210 of the base 21, that is, the coupling member 6 provided to the coupling board 212 is located lower in height than top surface 210 of the base 21, the heat sink block 20 can have a maximum heat dissipating area to dissipate heat generated by the heat generating component rapidly.

The heat generating component can be a CPU, or a semiconductor package that generates heat during operation thereof, etc.

The heat sink block 20 comprises a plurality of heat sink fins arranged at intervals to increase the heat dissipating area. The coupling board 212 and the base 21 are integrally formed, and the coupling board 212 is extended from the base 21 horizontally in relation to the base 21.

The coupling member 6 can be a bolt, the installing portion 2120 can be an opening, and the coupling portion 30 can be a screw hole.

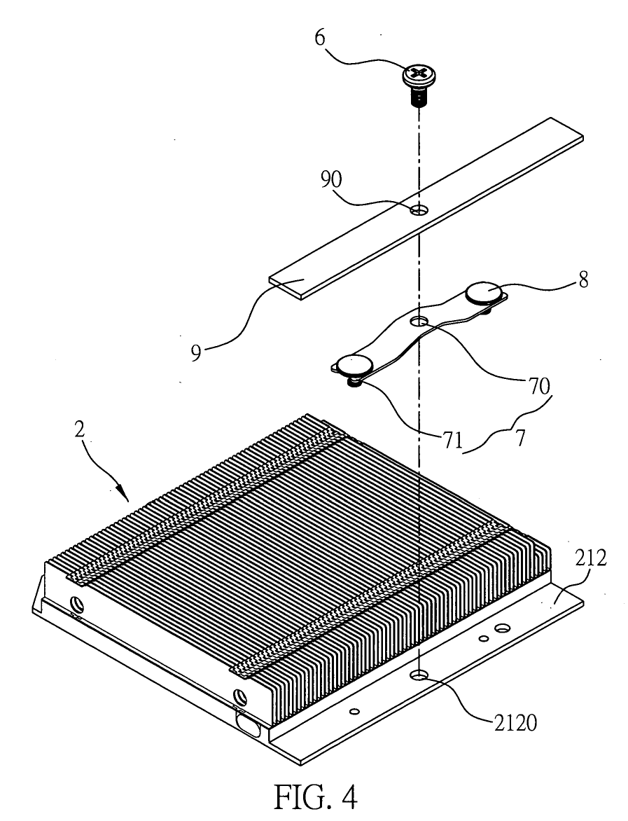

As shown in FIG. 4, the coupling board 212 can further be provided with an arc flexible piece 7 thereon, wherein the arc flexible piece 7 comprises an opening 70 corresponding to the installing portion 2120, and clips 71 formed on two ends of the flexible piece 7 and for clamping rivets 8 that are to be fixed to the coupling board 212. The coupling member 6 can be inserted in the opening 70 and the installing portion 2120 to be fixed to the coupling portion 30, thereby enhancing the coupling effect. The coupling board 212 can further be provided with a pressing board 9 on the arc flexible piece 7, wherein the pressing board 9 is formed with an opening 90 communicating with the opening 70 of the arc flexible piece 7. The pressing board 9 covers the arc flexible piece 7, and the coupling member 6 is also used to fix the pressing board 9 to the arc flexible piece 7. The pressing board 9 is used to evenly spread a pressure exerted from the arc flexible piece 7 to the coupling board 212. The pressing board 9 cooperates with the rivets 8 to limit an insertion depth of the coupling member 6 so as to avoid any damage to component(s) caused by over screwing of the coupling member 6.

Compared with the conventional heat dissipating device having the screwing elements thereof that impede flow of heat during dissipation, the heat dissipating device of the present invention has the heat sink block mounted on the top surface of the base, and uses the coupling member provided to the coupling board to fix the base to the frame-shaped carrier where the heat generating component is mounted, wherein the coupling board is located lower in height than the top surface of the base, such that the heat sink block can have a maximum heat dissipating area, and flow of the heat from the heat generating component during dissipating would not be affected by the coupling board with the coupling member.

Furthermore, as the base is located between the heat sink block and the heat generating component, and the heat sink block is mounted on the top surface of the base, the heat form the heat generating component can be spread to heat sink block evenly via the base, so as to avoid the heat being perpetually absorbed by a particular area of the heat sink block, such that the heat dissipating efficiency is not degraded.

Therefore, the heat dissipating device of the present invention overcomes the drawback in the prior art and improves the heat dissipating efficiency as compared with the prior art.

The present invention has been described using exemplary preferred embodiments above, however, it is to be understood that the scope of the present invention is not limited to the disclosed embodiments. On the contrary, it is intended to cover various modifications and similar changes. The scope of the claims, therefore, should be accorded the broadest interpretation so as to encompass all such modifications and similar arrangements.

What is claimed is:

1. A heat dissipating device for a heat generating component mounted on a frame-shaped carrier, the heat dissipating device comprising:
a heat sink block; and
a base having a top surface and a bottom surface, wherein the heat sink block is mounted on the top surface of the base, and a coupling board is formed on each of two opposites sides of the base at a position close to the bottom surface and lower in height than the top surface of the base, wherein the coupling board is formed with an installing portion for being coupled to a coupling portion of the frame-shaped carrier, so as to fix the base to the frame-shaped carrier via the coupling board that is located lower in height than the top surface of the base and allow the bottom surface of the base to cover the heat generating component on the frame-shaped carrier, to thereby make the heat sink block have a maximum heat dissipating area to dissipate heat generated by the heat generating component.

2. The heat dissipating device of claim 1, wherein the heat generating component is one of a central processing unit and a semiconductor package that generates heat in operation thereof.

3. The heat dissipating device of claim 1, wherein the heat sink block comprises a plurality of heat sink fins arranged at intervals to increase the heat dissipating area.

4. The heat dissipating device of claim 1, wherein the coupling board is integrally protruded from the base.

5. The heat dissipating device of claim 1, wherein the installing portion is an opening and the coupling portion is a screw hole.

6. The heat dissipating device of claim 5, wherein, the installing portion and the coupling portion are coupled to each other by a coupling member.

7. The heat dissipating device of claim 6, wherein the coupling member is a bolt.
